(19) United States
(12) Patent Application Publication
(10) Pub. No.: US 2025/0169334 A1
(43) Pub. Date: May 22, 2025

(54) DISPLAY APPARATUS AND METHOD OF MANUFACTURING THE SAME

(71) Applicant: Samsung Display Co., LTD., Yongin-si (KR)

(72) Inventors: Hyunsup YOON, Yongin-si (KR); Jongwoo KIM, Yongin-si (KR); Soyoung OH, Yongin-si (KR); Woosuk JUNG, Yongin-si (KR); Jaeheung HA, Yongin-si (KR)

(21) Appl. No.: 18/805,239

(22) Filed: Aug. 14, 2024

(30) Foreign Application Priority Data
Nov. 20, 2023 (KR) 10-2023-0161448

(51) Int. Cl. H10K 59/80; H10K 59/12

(52) U.S. Cl. CPC H10K 59/873; H10K 59/1201; H10K 59/879

(57) ABSTRACT

A display apparatus includes: a substrate, a light-emitting element disposed on the substrate, and an encapsulation layer covering the light-emitting element and including a first inorganic thin-film encapsulation layer, a second inorganic thin-film encapsulation layer, and a hybrid layer. The second inorganic thin-film encapsulation layer is disposed on the first inorganic thin-film encapsulation layer and has a film density less than a film density of the first inorganic thin-film encapsulation layer, and the hybrid layer is disposed on the second inorganic thin-film encapsulation layer and includes a silicon element and a carbon element and further includes a nitrogen element or an oxygen element.

This application claims priority to Korean Patent Application No. 10-2023-0161448, filed on Nov. 20, 2023, and all the benefits accruing therefrom under 35 U.S.C. § 119, the content of which in its entirety is herein incorporated by reference.

### BACKGROUND

### 1. Field

One or more embodiments relate to a display apparatus and a method of manufacturing the display apparatus.

### 2. Description of the Related Art

A display apparatus visually displays data. Recently, the usage of display apparatuses has diversified. In addition, as display apparatuses have become thinner and lighter, their range of use has been extended.

To implement thin and lightweight display apparatuses, the display apparatuses may be configured to include an emission area that is encapsulated using a thin-film encapsulation layer instead of an encapsulation substrate including a glass material. The thin-film encapsulation layer may be configured to prevent penetration of impurities such as oxygen or moisture into a light-emitting element, and planarize the upper surface of a display area by covering the display area of display apparatuses.

### SUMMARY

One or more embodiments include a thin and lightweight display apparatus. However, such a technical objective is just an example, and the disclosure is not limited thereto.

Additional aspects will be set forth in part in the description which follows and, in part, will be apparent from the description, or may be learned by practice of the presented embodiments of the disclosure.

According to one or more embodiments, a display apparatus includes: a substrate; a light-emitting element disposed on the substrate; and an encapsulation layer covering the light-emitting element, and including a first inorganic thin-film encapsulation layer, a second inorganic thin-film encapsulation layer and a hybrid layer, wherein the second inorganic thin-film encapsulation layer is disposed on the first inorganic thin-film encapsulation layer and has a film density less than a film density of the first inorganic thin-film encapsulation layer, and the hybrid layer is disposed on the second inorganic thin-film encapsulation layer and includes a silicon element and a carbon element and further includes a nitrogen element or an oxygen element.

A thickness of the first inorganic thin-film encapsulation layer may be less than a thickness of the second inorganic thin-film encapsulation layer.

The hybrid layer may have a film density less than the film density of the first inorganic thin-film encapsulation layer.

Each of the first inorganic thin-film encapsulation layer and the second inorganic thin-film encapsulation layer may include a silicon element and a nitrogen element.

A ratio of the nitrogen element to the silicon element in the first inorganic thin-film encapsulation layer may be less than a ratio of the nitrogen element to the silicon element in the second inorganic thin-film encapsulation layer.

The film density of the first inorganic thin-film encapsulation layer may be in a range of about 2.70 grams per cubic centimeter (g/cm³) to about 4.00 g/cm³.

The film density of the second inorganic thin-film encapsulation layer may be in a range of about 1.70 g/cm³ to about 2.10 g/cm³.

A refractive index of the first inorganic thin-film encapsulation layer may be greater than a refractive index of the second inorganic thin-film encapsulation layer.

The encapsulation layer may further include a third inorganic thin-film encapsulation layer disposed on the hybrid layer.

A film density of the third inorganic thin-film encapsulation layer may be greater than the film density of the second inorganic thin-film encapsulation layer.

The hybrid layer may include at least one of silicon carbonitride (SiCₓN_{y}), silicon oxycarbide (SiOₓC_{y}), or silicon oxycarbonitride (SiOₓC_{y}N_{z}).

According to one or more embodiments, a display apparatus includes: a substrate; a light-emitting element disposed on the substrate; and an encapsulation layer covering the light-emitting element, where the encapsulation layer includes a first inorganic thin-film encapsulation layer disposed in a lowermost portion of the encapsulation layer, a second inorganic thin-film encapsulation layer disposed directly on the first inorganic thin-film encapsulation layer and having a film density less than a film density of the first inorganic thin-film encapsulation layer, and a hybrid layer disposed on the second inorganic thin-film encapsulation layer and having a film density less than the film density of the first inorganic thin-film encapsulation layer.

The hybrid layer may include a silicon element and a carbon element and may further include a nitrogen element or an oxygen element.

A thickness of the first inorganic thin-film encapsulation layer may be less than a thickness of the second inorganic thin-film encapsulation layer.

According to one or more embodiments, a method of manufacturing a display apparatus includes: forming a light-emitting element over a substrate; forming a first inorganic thin-film encapsulation layer on the light-emitting element; forming, on the first inorganic thin-film encapsulation layer, a second inorganic thin-film encapsulation layer having a film density less than a film density of the first inorganic thin-film encapsulation layer; and forming, on the second inorganic thin-film encapsulation layer, a hybrid layer including a silicon element and a carbon element and further including a nitrogen element or an oxygen element.

A deposition rate of the first inorganic thin-film encapsulation layer may be less than a deposition rate of the second inorganic thin-film encapsulation layer.

A thickness of the first inorganic thin-film encapsulation layer may be less than a thickness of the second inorganic thin-film encapsulation layer.

The hybrid layer may have a film density less than the film density of the first inorganic thin-film encapsulation layer.

The forming of the first inorganic thin-film encapsulation layer may include using an atomic layer deposition method.

The forming of the hybrid layer may include using a precursor containing at least one of a compound having an N—Si bond or a compound having an O—Si-based bond.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a schematic perspective view of a display apparatus according to an embodiment;

FIGS. 2A and 2B are examples of equivalent circuit diagrams of a pixel of the display apparatus according to an embodiment;

FIG. 3 is a schematic cross-sectional view of a display apparatus according to an embodiment;

FIG. 4 is a schematic cross-sectional view of an encapsulation layer according to an embodiment;

FIG. 5 is a schematic cross-sectional view of an encapsulation layer according to another embodiment;

FIG. 6 is a schematic cross-sectional view of a display apparatus according to an embodiment;

FIG. 7 is a flowchart showing a method of manufacturing a display apparatus according to an embodiment;

FIG. 8 is a schematic flowchart showing a method of manufacturing a display apparatus according to another embodiment; and

FIG. 9 is a view showing TEM analysis results according to an embodiment and a comparative example.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present description. As used herein, the term “and/or” includes any and all combinations of one or more of the associated listed items. Throughout the disclosure, the expression “at least one of a, b or c” indicates only a, only b, only c, both a and b, both a and c, both b and c, all of a, b, and c, or variations thereof.

As the disclosure allows for various changes and numerous embodiments, certain embodiments will be illustrated in the drawings and described in the written description. Effects and features of the disclosure, and methods for achieving them will be clarified with reference to embodiments described below in detail with reference to the drawings. However, the disclosure is not limited to the following embodiments and may be embodied in various forms.

Hereinafter, embodiments will be described with reference to the accompanying drawings, wherein same or like reference numerals refer to same or corresponding elements throughout and a repeated description thereof is omitted.

While such terms as “first” and “second” may be used to describe various components, such components must not be limited to the above terms. The above terms are used to distinguish one component from another.

The singular forms “a,” “an,” and “the” as used herein are intended to include the plural forms as well unless the context clearly indicates otherwise.

It will be understood that the terms “comprise,” “comprising,” “include” and/or “including” as used herein specify the presence of stated features or components but do not preclude the addition of one or more other features or components.

It will be further understood that, when a layer, region, or element is referred to as being “on” another layer, region, or element, it can be directly or indirectly on the other layer, region, or element. That is, for example, intervening layers, regions, or elements may be present.

Sizes of elements in the drawings may be exaggerated or reduced for convenience of explanation. As an example, the size and thickness of each element shown in the drawings are arbitrarily represented for convenience of description, and thus, the disclosure is not necessarily limited thereto.

In the case where a certain embodiment may be implemented differently, a specific process order may be performed in the order different from the described order. As an example, two processes successively described may be simultaneously performed substantially and performed in the opposite order.

It will be understood that when a layer, region, or element is referred to as being “connected” to another layer, region, or element, it may be “directly connected” to the other layer, region, or element or may be “indirectly connected” to the other layer, region, or element with other layer, region, or element located therebetween. For example, it will be understood that when a layer, region, or element is referred to as being “electrically connected” to another layer, region, or element, it may be “directly electrically connected” to the other layer, region, or element or may be “indirectly electrically connected” to other layer, region, or element with another layer, region, or element disposed therebetween.

The x-axis, the y-axis and the z-axis are not limited to three axes of the rectangular coordinate system, and may be interpreted in a broader sense. For example, the x-axis, the y-axis, and the z-axis may be perpendicular to one another, or may represent different orientations that are not perpendicular to one another.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±10%, 5% or 2% of the stated value.

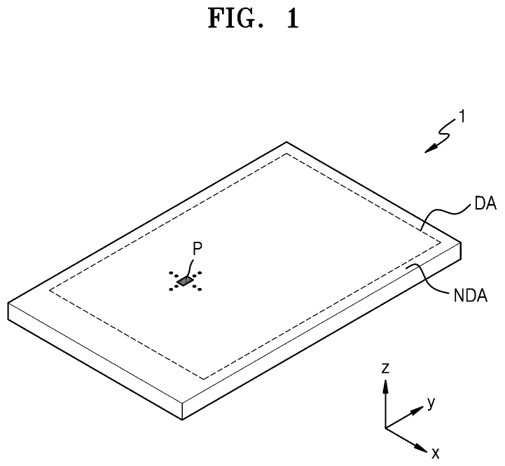

FIG. 1 is a schematic perspective view of a display apparatus 1 according to an embodiment.

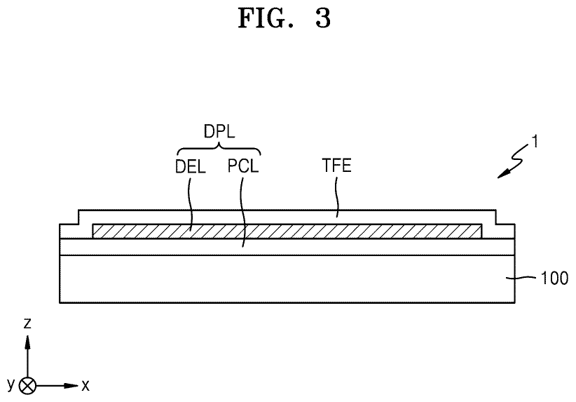

Referring to FIG. 1, the display apparatus 1 may include a display area DA and a non-display area NDA. A plurality of pixels P are arranged in the display area DA, and the non-display area NDA is outside the display area DA. The non-display area NDA may surround the display area DA entirely. The display area DA and the non-display area NDA may be included in a substrate 100 (see FIG. 3) included in the display apparatus 1.

Each pixel P of the display apparatus 1 is configured to emit light of a preset color. The display apparatus 1 may be configured to display images using light emitted from the plurality of pixels P. As an example, each pixel P may be configured to emit red, green, or blue light.

As shown in FIG. 1, the display area DA may have a polygonal shape such as a quadrangular shape. As an example, the display area DA may have a rectangular shape in which a horizontal length thereof is greater than a vertical length, a rectangular shape in which a horizontal length thereof is less than a vertical length, or a square shape. Alternatively, the display area DA may have various shapes such as an elliptical shape or a circular shape.

The non-display area NDA may be a region in which pixels P are not arranged. A driver and the like configured to provide electrical signals or power to the pixels P may be arranged in the non-display area NDA. Pads (not shown) may be arranged in the non-display area NDA, where various kinds of electronic elements or a printed circuit board may be electrically connected to the pads. The pads may be apart from each other in the non-display area NDA and electrically connected to a printed circuit board or an integrated circuit element.

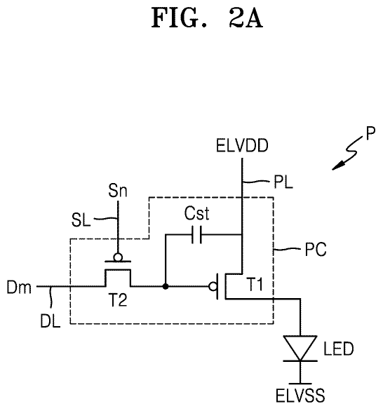

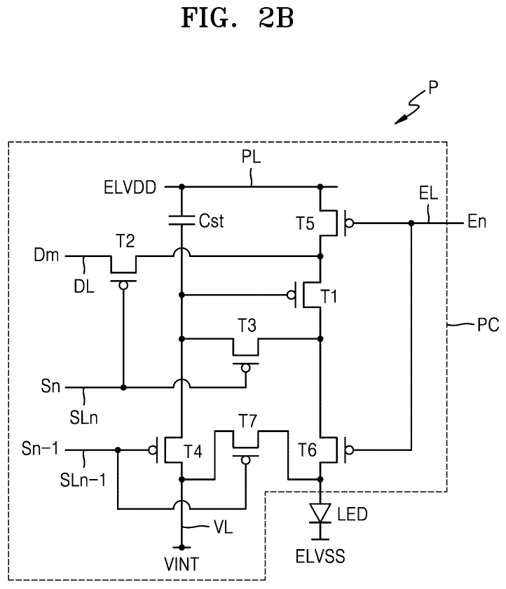

FIGS. 2A and 2B are examples of equivalent circuit diagrams of the pixel P of the display apparatus 1 according to an embodiment.

Referring to FIG. 2A, each pixel P may include a pixel circuit PC and a light-emitting element LED connected to the pixel circuit PC, where the pixel circuit PC is connected to a scan line SL and a data line DL.

The pixel circuit PC may include a driving thin-film transistor T1, a switching thin-film transistor T2, and a storage capacitor Cst.

The switching thin-film transistor T2 is configured to transfer a data signal Dm to the driving thin-film transistor T1 according to a scan signal Sn input through the scan line SL, where the data signal Dm is input through the data line DL.

The storage capacitor Cst is connected to the switching thin-film transistor T2 and a driving voltage line PL and configured to store a voltage corresponding to a difference between a voltage transferred from the switching thin-film transistor T2 and a first power voltage ELVDD (or a driving voltage) supplied to the driving voltage line PL.

The driving thin-film transistor T1 may be connected to the driving voltage line PL and the storage capacitor Cst and configured to control a driving current according to the voltage stored in the storage capacitor Cst, the driving current flowing from the driving voltage line PL to the light-emitting element LED. The light-emitting element LED may be configured to emit light having a preset brightness corresponding to the driving current.

Although it is described with reference to FIG. 2A that the pixel circuit PC includes two thin-film transistors and one capacitor, the embodiment is not limited thereto.

Referring to FIG. 2B, the pixel circuit PC may include the driving thin-film transistor T1, the switching thin-film transistor T2, a compensation thin-film transistor T3, a first initialization thin-film transistor T4, a first emission control thin-film transistor T5, a second emission control thin-film transistor T6, and a second initialization thin-film transistor T7.

Although it is shown in FIG. 2B that the signal lines SLn, SLn−1, EL, DL, an initialization voltage line VL, and the driving voltage line PL are provided for each pixel, the embodiment is not limited thereto. In another embodiment, at least one of the signal lines SLn, SLn−1, EL, and DL, and/or the initialization voltage line VL may be shared by adjacent pixels.

A drain electrode of the driving thin-film transistor T1 may be electrically connected to the light-emitting element LED through the second emission control thin-film transistor T6. The driving thin-film transistor T1 is configured to receive a data signal Dm and supply the driving current to the light-emitting element LED according to a switching operation of the switching thin-film transistor T2.

A gate electrode of the switching thin-film transistor T2 is connected to the first scan line SLn, and a source electrode of the switching thin-film transistor T2 is connected to the data line DL. A drain electrode of the switching thin-film transistor T2 may be connected to the source electrode of the driving thin-film transistor T1 and connected to the driving voltage line PL through the first emission control thin-film transistor T5.

The switching thin-film transistor T2 may be turned on according to a first scan signal Sn transferred through the first scan line SLn and may perform a switching operation of transferring a data signal Dm to the source electrode of the driving thin-film transistor T1, where the data signal Dm is transferred through the data line DL.

A gate electrode of the compensation thin-film transistor T3 may be connected to the first scan line SLn. A source electrode of the compensation thin-film transistor T3 may be connected to the drain electrode of the driving thin-film transistor T1 and connected to a pixel electrode of the light-emitting element LED through the second emission control thin-film transistor T6. A drain electrode of the compensation thin-film transistor T3 may be connected to one electrode of the storage capacitor Cst, a source electrode of the first initialization thin-film transistor T4, and the gate electrode of the driving thin-film transistor T1. The compensation thin-film transistor T3 is configured to be turned on according to a first scan signal Sn transferred through the first scan line SL, and diode-connect the driving thin-film transistor T1 by connecting the gate electrode and the drain electrode of the driving thin-film transistor T1 to each other.

A gate electrode of the first initialization thin-film transistor T4 may be connected to the second scan line SLn−1 (previous scan line). A drain electrode of the first initialization thin-film transistor T4 may be connected to the initialization voltage line VL. A source electrode of the first initialization thin-film transistor T4 may be connected to one electrode of the storage capacitor Cst, the drain electrode of the compensation thin-film transistor T3, and the gate electrode of the driving thin-film transistor T1. The first initialization thin-film transistor T4 may be turned on according to a second scan signal Sn−1 received through the second scan line SLn−1, and may perform an initialization operation of initializing the voltage of the gate electrode of the driving thin-film transistor T1 by transferring an initialization voltage VINT to the gate electrode of the driving thin-film transistor T1.

A gate electrode of the first emission control thin-film transistor T5 may be connected to the emission control line EL. A source electrode of the first emission control thin-film transistor T5 may be connected to the driving voltage line PL. A drain electrode of the first emission control thin-film transistor T5 is connected to the source electrode of the driving thin-film transistor T1 and the drain electrode of the switching thin-film transistor T2.

A gate electrode of the second emission control thin-film transistor T6 may be connected to the emission control line EL. A source electrode of the second emission control thin-film transistor T6 may be connected to the drain electrode of the driving thin-film transistor T1 and the source electrode of the compensation thin-film transistor T3. A drain electrode of the second emission control thin-film transistor T6 may be electrically connected to the pixel electrode of the light-emitting element LED. The first emission control thin-film transistor T5 and the second emission control thin-film transistor T6 are simultaneously turned on according to an emission control signal En transferred through the emission control line EM, and the first power voltage ELVDD is transferred to the light-emitting element LED, and thus, the driving current flows through the light-emitting element LED.

A gate electrode of the first initialization thin-film transistor T7 may be connected to the second scan line SLn−1. A source electrode of the second initialization thin-film transistor T7 may be connected to the pixel electrode of the light-emitting element LED. A drain electrode of the second initialization thin-film transistor T7 may be connected to the initialization voltage line VL. The second initialization thin-film transistor T7 may be turned on according to a second scan signal Sn−1 transferred through the second scan line SLn−1 and may initialize the pixel electrode of the light-emitting element LED.

Although it is shown in FIG. 2B that the first initialization thin-film transistor T4 and the second initialization thin-film transistor T7 are connected to the second scan line SLn−1, the embodiment is not limited thereto. In another embodiment, the first initialization thin-film transistor T4 may be connected to the second scan line SLn−1, which is a previous scan line, and driven according to a second scan signal Sn−1, and the second initialization thin-film transistor T7 may be connected to a separate signal line (e.g., next scan line), and driven according to a signal transferred to the relevant scan line.

The other electrode of the storage capacitor Cst may be connected to the driving voltage line PL. One electrode of the storage capacitor Cst may be connected to the gate electrode of the driving thin-film transistor T1, the drain electrode of the compensation thin-film transistor T3, and the source electrode of the first initialization thin-film transistor T4.

An opposite electrode (e.g., a cathode) of the light-emitting element LED is configured to receive a second power voltage ELVSS (or a common power voltage). The light-emitting element LED may be configured to emit light by receiving the driving current from the driving thin-film transistor T1.

The pixel circuit PC is not limited to the number of thin-film transistors, the number of storage capacitors, and the circuit design described with reference to FIGS. 2A and 2B, and the number of thin-film transistors, the number of storage capacitors, and the circuit design may be variously changed.

FIG. 3 is a schematic cross-sectional view of the display apparatus 1 according to an embodiment.

Referring to FIG. 3, the display apparatus 1 may include a substrate 100, a display layer PDL on the substrate 100, and an encapsulation layer TFE on the display layer DPL. The display layer DPL may include a pixel circuit layer PCL and a display element layer DEL, where the pixel circuit layer PCL includes a pixel circuit and insulating layers, and the display element layer DEL is disposed on the pixel circuit layer PCL and includes a plurality of display elements.

The substrate 100 may include glass, metal, or polymer resin. The polymer resin may include, for example, polyethersulphone, polyacrylate, polyetherimide, polyethylene naphthalate, polyethylene terephthalate, polyphenylene sulfide, polyarylate, polyimide, polycarbonate, cellulose acetate propionate, or a mixture thereof. The substrate 100 may have a multi-layered structure including two layers each including the polymer resin, and a barrier layer including an inorganic material (such as silicon oxide (SiOₓ), silicon nitride (SiNₓ), and silicon oxynitride (SiOₓN_{y}) therebetween. However, various modifications may be made.

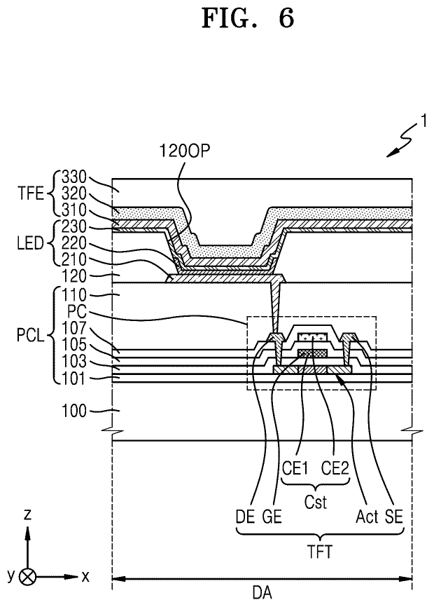

The display element layer DEL may include a display element such as the light-emitting element LED (see FIG. 6). The pixel circuit layer PCL may include the pixel circuit PC (see FIG. 6) and the insulating layers, where the pixel circuit PC is connected to the light-emitting element LED (see FIG. 6). As an example, the pixel circuit layer PCL may include a plurality of transistors, a plurality of storage capacitors, and insulating layers therebetween.

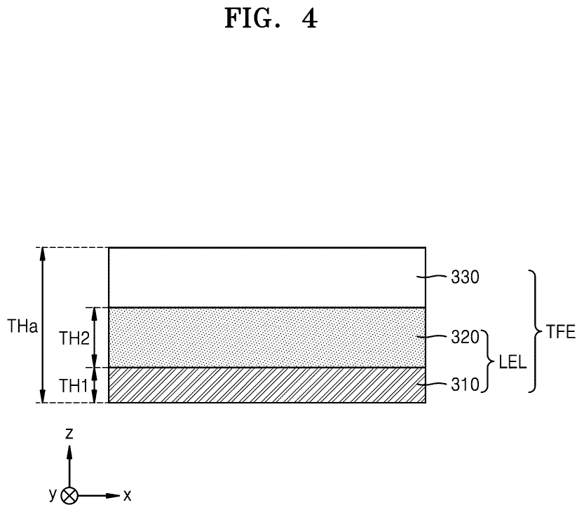

The encapsulation layer TFE may cover the display element layer DEL. That is, the encapsulation layer TFE may cover the display elements included in the display element layer DEL. The encapsulation layer TFE may include at least an inorganic thin-film encapsulation layer (e.g., a first inorganic thin-film encapsulation layer 310 and/or a second inorganic thin-film encapsulation layer 320) and a hybrid layer 330 described below with reference to FIG. 4.

FIG. 4 is a schematic cross-sectional view of the encapsulation layer TFE according to an embodiment.

Referring to FIG. 4, the encapsulation layer TFE may include a lower thin-film encapsulation layer LEL and the hybrid layer 330. The lower thin-film encapsulation layer LEL may be disposed on the display element layer DEL (see FIG. 3) including the display elements, and the hybrid layer 330 may be disposed on the lower thin-film encapsulation layer LEL. That is, the lower thin-film encapsulation layer LEL may be disposed under the hybrid layer 330.

The lower thin-film encapsulation layer LEL may include at least two inorganic thin-film encapsulation layers respectively having different film densities. The lower thin-film encapsulation layer LEL may include a first inorganic thin-film encapsulation layer 310 and a second inorganic thin-film encapsulation layer 320 disposed on the first inorganic thin-film encapsulation layer 310.

The first inorganic thin-film encapsulation layer 310 is disposed in the lowermost portion of the encapsulation layer TFE and may be denoted by a lowermost thin-film encapsulation layer. That is, the first inorganic thin-film encapsulation layer 310 may be a layer disposed to be most adjacent to the light-emitting element LED (see FIG. 6) among the plurality of layers of the encapsulation layer TFE. The first inorganic thin-film encapsulation layer 310 may be a layer whose distance from the substrate 100 (see FIG. 6) is smallest among the plurality of layers of the encapsulation layer TFE.

The second inorganic thin-film encapsulation layer 320 may be disposed directly on the first inorganic thin-film encapsulation layer 310. The second inorganic thin-film encapsulation layer 320 may be disposed between the first inorganic thin-film encapsulation layer 310 and the hybrid layer 330.

The first inorganic thin-film encapsulation layer 310 may be a high-density layer, and the second inorganic thin-film encapsulation layer 320 may be a low-density layer. That is, a film density of the second inorganic thin-film encapsulation layer 320 may be less than a film density of the first inorganic thin-film encapsulation layer 310. As an example, a film density of the first inorganic thin-film encapsulation layer 310 may be in a range of about 2.70 g/cm³ to about 4.00 g/cm³. As an example, a film density of the second inorganic thin-film encapsulation layer 320 may be in a range of about 1.7 g/cm³ to about 2.10 g/cm³.

The first inorganic thin-film encapsulation layer 310 and the second inorganic thin-film encapsulation layer 320 may be formed by being deposited at different deposition rates from each other. A deposition rate of the first inorganic thin-film encapsulation layer 310 may be less than a deposition rate of the second inorganic thin-film encapsulation layer 320. As an example, a deposition rate of the first inorganic thin-film encapsulation layer 310 may be less than 300 angstroms per minute (A/min). As an example, a deposition rate of the second inorganic thin-film encapsulation layer 320 may be 300 Å/min or more.

In an embodiment, although the first inorganic thin-film encapsulation layer 310 and the second inorganic thin-film encapsulation layer 320 may be deposited by different deposition methods from each other, the embodiment is not limited thereto. In another embodiment, the first inorganic thin-film encapsulation layer 310 and the second inorganic thin-film encapsulation layer 320 may be deposited by the same deposition method, but may be formed to have different film densities from each other by varying the deposition rate. As an example, the first inorganic thin-film encapsulation layer 310 may be formed by an atomic layer deposition (“ALD”). As an example, the second inorganic thin-film encapsulation layer 320 may be formed by chemical vapor deposition (“CVD”) or ALD. The ALD may include, for example, plasma enhanced ALD (“PEALD”). The CVD may include, for example, plasma enhanced CVD (“PECVD”). Accordingly, the first inorganic thin-film encapsulation layer 310 may have a single atomic layer.

A thickness TH1 of the first inorganic thin-film encapsulation layer 310 may be less than a thickness TH2 of the second inorganic thin-film encapsulation layer 320.

The first inorganic thin-film encapsulation layer 310 and the second inorganic thin-film encapsulation layer 320 may each have a barrier characteristic of preventing the penetration of impurities such as oxygen or moisture.

In an embodiment, because the first inorganic thin-film encapsulation layer 310 of a high density (i.e., high film density) is formed together with the second inorganic thin-film encapsulation layer 320 of a low density (i.e., low film density), the thickness of the lower thin-film encapsulation layer LEL in an embodiment may be formed thin compared to the case where the lower thin-film encapsulation layer includes only the second inorganic thin-film encapsulation layer 320 of a low density. In addition, in a case where only the first inorganic thin-film encapsulation layer 310 of a high density is formed, a process efficiency may be problematic due to the low deposition rate of the first inorganic thin-film encapsulation layer 310 of a high density. In contrast, in an embodiment, because the first inorganic thin-film encapsulation layer 310 and the second inorganic thin-film encapsulation layer 320 are formed together, a process efficiency is not reduced compared to the case in which only the first inorganic thin-film encapsulation layer 310 of a high density is formed, and a barrier characteristic of the lower thin-film encapsulation layer LEL may be effectively improved as described below.

In the case where the second inorganic thin-film encapsulation layer 320 of a low density is formed directly on the light-emitting element LED without the first inorganic thin-film encapsulation layer 310 of a high density therebetween, the film density is low and the barrier characteristic of the second inorganic thin-film encapsulation layer 320 may be reduced. In contrast, in an embodiment, because the first inorganic thin-film encapsulation layer 310 of a high density is formed first as the lower portion of the encapsulation layer TFE (e.g., formed directly on the light-emitting element LED), and then the second inorganic thin-film encapsulation layer 320 of a low density is formed on the first inorganic thin-film encapsulation layer 310, the first inorganic thin-film encapsulation layer 310 may serve as a seed layer. Accordingly, compared to the case where the second inorganic thin-film encapsulation layer 320 is formed directly on the light-emitting element LED (see FIG. 6) without formation of the first inorganic thin-film encapsulation layer 310, the second inorganic thin-film encapsulation layer 320 in an embodiment may have a relatively high film density at the interface with a different layer (e.g., the first inorganic thin-film encapsulation layer 310) adjacent to the second inorganic thin-film encapsulation layer 320. Accordingly, the barrier characteristic of the lower thin-film encapsulation layer LEL may be effectively improved.

The first inorganic thin-film encapsulation layer 310 and the second inorganic thin-film encapsulation layer 320 may each include an inorganic material. As an example, the first inorganic thin-film encapsulation layer 310 and the second inorganic thin-film encapsulation layer 320 may each include a silicon (Si) element and a nitrogen (N) element. As an example, the first inorganic thin-film encapsulation layer 310 and the second inorganic thin-film encapsulation layer 320 may each include silicon nitride (SiNₓ) or silicon oxynitride (SiOₓN_{y}). As an example, the first inorganic thin-film encapsulation layer 310 and the second inorganic thin-film encapsulation layer 320 may each be formed by using a compound containing a silicon element and a nitrogen element as a precursor. As an example, the first inorganic thin-film encapsulation layer 310 and the second inorganic thin-film encapsulation layer 320 may each include a silicone amine-based precursor. The ratio of nitrogen elements to silicon elements (N/Si ratio) in the first inorganic thin-film encapsulation layer 310 may be less than the ratio of nitrogen elements to silicon elements (N/Si ratio) in the second inorganic thin-film encapsulation layer 320. As an example, the ratio of nitrogen elements to silicon elements in the first inorganic thin-film encapsulation layer 310 may be less than 0.75, and the ratio of nitrogen elements to silicon elements in the second inorganic thin-film encapsulation layer 320 may exceed 0.77.

A refractive index of the first inorganic thin-film encapsulation layer 310 may be greater than a refractive index of the second inorganic thin-film encapsulation layer 320. As an example, the refractive index of the first inorganic thin-film encapsulation layer 310 may be 1.85 or more. As an example, the refractive index of the second inorganic thin-film encapsulation layer 320 may be about 1.75 to about 1.90.

The hybrid layer 330 may be disposed on the second inorganic thin-film encapsulation layer 320. In an embodiment, the hybrid layer 330 may be disposed directly on the second inorganic thin-film encapsulation layer 320. The hybrid layer 330 may be an organic-inorganic hybrid layer including organic moiety. As an example, the hybrid layer 330 may include at least a silicon element and a carbon element and may further include a nitrogen element or an oxygen element. As an example, the hybrid layer 330 may include at least one of silicon carbonitride (SiCₓN_{y}), silicon oxycarbide (SiOₓC_{y}), or silicon oxycarbonitride (SiOₓC_{y}N_{z}). As an example, the hybrid layer 330 may be formed using a precursor containing at least one of a compound having an N—Si bond or a compound having an O—Si-based bond. As an example, the hybrid layer 330 may include, as a precursor, at least one of cyclosilazane, trisilyamine, bis(diethylamino)silane, bis(t-butylamino)silane, tris(dimethylamino)silane, tris(isopropylamino)silane, tetrakis(dimethylamino)silane, tri(isopropyl)cyclotrisilazane, or tetramethyldisilazane.

The hybrid layer 330 may have both a barrier characteristic that prevents the penetration of impurities such as oxygen or moisture, and a planarization characteristic. Accordingly, the encapsulation layer TFE according to an embodiment may be configured to prevent the penetration of impurities and planarize the upper surface of the encapsulation layer TFE even without an organic encapsulation layer including monomer.

A film density of the hybrid layer 330 may be less than a film density of the first inorganic thin-film encapsulation layer 310. Although a film density of the hybrid layer 330 may be, for example, about 1.7 g/cm³ to about 2.10 g/cm³, the embodiment is not limited thereto.

A deposition rate of the hybrid layer 330 may be greater than a deposition rate of the first inorganic thin-film encapsulation layer 310. As an example, a deposition rate of the hybrid layer 330 may be 300 Å/min or more.

A refractive index of the hybrid layer 330 may be less than a refractive index of the first inorganic thin-film encapsulation layer 310. As an example, although a refractive index of the hybrid layer 330 may be about 1.75 to about 1.90, the embodiment is not limited thereto.

Because the lower thin-film encapsulation layer LEL in an embodiment includes both the first inorganic thin-film encapsulation layer 310 of a high density and the second inorganic thin-film encapsulation layer 320 of a low density and is formed to have a thin thickness, a barrier characteristic of the lower thin-film encapsulation layer LEL may be effectively improved. Accordingly, a thickness THa of the encapsulation layer TFE according to an embodiment may be less than the case where the encapsulation layer TFE includes only the second inorganic thin-film encapsulation layer 320 of a low density without the first inorganic thin-film encapsulation layer 310 of a high density. In addition, because the hybrid layer 330 on the lower thin-film encapsulation layer LEL has both a barrier characteristic and a planarization characteristic, the encapsulation layer TFE may not include a separate organic thin-film encapsulation layer. Accordingly, the thickness THa of the encapsulation layer TFE may be less than the case where the organic thin-film encapsulation layer is provided.

Because the lower thin-film encapsulation layer LEL includes both the first inorganic thin-film encapsulation layer 310 of a high density and the second inorganic thin-film encapsulation layer 320 of a low density, the lower thin-film encapsulation layer LEL may be formed to have a thin thickness. Furthermore, because the hybrid layer 330 has both a barrier characteristic and a planarization characteristic, a separate organic thin-film encapsulation layer may not be formed, and thus, the thickness of the encapsulation layer TFE may be formed thin. As an example, the thickness THa of the encapsulation layer TFE may be about 0.4 micrometers (μm) to about 2 μm. As an example, the thickness THa of the encapsulation layer TFE may be about 0.4 μm to about 1 μm.

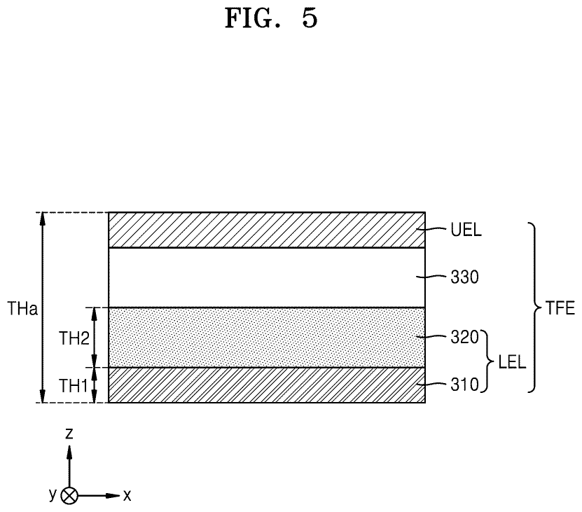

FIG. 5 is a schematic cross-sectional view of the encapsulation layer TFE according to another embodiment. FIG. 5 is a view showing a modified embodiment of FIG. 4. Hereinafter, descriptions repeated by those described with reference to FIG. 4 will be omitted.

Referring to FIG. 5, the encapsulation layer TFE may include a lower thin-film encapsulation layer LEL, the hybrid layer 330, and an upper thin-film encapsulation layer UEL. The lower thin-film encapsulation layer LEL may be disposed on the display element layer DEL (see FIG. 3) including the display elements, the hybrid layer 330 may be disposed on the lower thin-film encapsulation layer LEL, and the upper thin-film encapsulation layer UEL may be disposed on the hybrid layer 330. The first and second inorganic thin-film encapsulation layers 310 and 320 are layers disposed under the hybrid layer 330, and the upper thin-film encapsulation layer UEL may be a layer disposed on the hybrid layer 330.

A film density of the upper thin-film encapsulation layer UEL may be greater than a film density of the second inorganic thin-film encapsulation layer 320. As an example, a film density of the upper thin-film encapsulation layer UEL may be in a range of about 2.70 g/cm³ to about 4.00 g/cm³.

The upper thin-film encapsulation layer UEL may be formed by being deposited at a deposition rate different from a deposition rate of the second inorganic thin-film encapsulation layer 320. A deposition rate of the upper thin-film encapsulation layer UEL may be less than a deposition rate of the second inorganic thin-film encapsulation layer 320. As an example, a deposition rate of the upper thin-film encapsulation layer UEL may be less than 300 Å/min.

The upper thin-film encapsulation layer UEL may include an inorganic material and be denoted by a “third inorganic thin-film encapsulation layer”. As an example, the upper thin-film encapsulation layer UEL may include at least a silicon (Si) element and a nitrogen (N) element. As an example, the upper thin-film encapsulation layer UEL may include silicon nitride (SiNₓ) or silicon oxynitride (SiOₓN_{y}). As an example, the upper thin-film encapsulation layer UEL may be formed by using a compound containing a silicon element and a nitrogen element as a precursor. As an example, the upper thin-film encapsulation layer UEL may be formed by using a silicone amine-based compound as a precursor. The ratio of nitrogen elements to silicon elements (N/Si ratio) in the upper thin-film encapsulation layer UEL may be less than the ratio of nitrogen elements to silicon elements (N/Si ratio) in the second inorganic thin-film encapsulation layer 320. As an example, the ratio of nitrogen elements to silicon elements in the upper thin-film encapsulation layer UEL may be less than 0.75.

A refractive index of the upper thin-film encapsulation layer UEL may be greater than a refractive index of the second inorganic thin-film encapsulation layer 320. As an example, the refractive index of the upper thin-film encapsulation layer UEL may be 1.85 or more.

Although it is shown in FIG. 5 that only the upper thin-film encapsulation layer UEL is disposed on the hybrid layer 330 in the encapsulation layer TFE, the embodiment is not limited thereto. In another embodiment, the encapsulation layer TFE may further include at least one thin-film encapsulation layer on the upper thin-film encapsulation layer UEL.

FIG. 6 is a schematic cross-sectional view of the display apparatus 1 according to an embodiment.

Referring to FIG. 6, the display apparatus 1 includes the light-emitting element LED, and the light-emitting element LED may be electrically connected to the pixel circuit PC disposed between the substrate 100 and the light-emitting element LED in a direction (e.g., a z direction) perpendicular to the substrate 100.

The display apparatus 1 may include the substrate 100, the pixel circuit layer PCL on the substrate 100, and the light-emitting element LED on the pixel circuit layer PCL.

The pixel circuit layer PCL may be a layer including the pixel circuit PC and insulating layers. The pixel circuit layer PCL may include a buffer layer 101, a first insulating layer 103, a second insulating layer 105, a third insulating layer 107, a thin-film transistor TFT, and a fourth insulating layer 110.

The buffer layer 101 is disposed on the substrate 100 and may planarize the upper surface of the substrate 100 and block the introduction of impurities from the substrate 100. The buffer layer 101 may include an inorganic insulating material such as silicon oxide (SiOₓ), silicon nitride (SiNₓ), and silicon oxynitride (SiOₓN_{y}). The buffer layer 101 may include a single layer or a multi-layered structure including the inorganic insulating material.

The pixel circuit PC may include at least one thin-film transistor TFT and a storage capacitor Cst. The thin-film transistor TFT may include a semiconductor layer Act, a gate electrode GE, a source electrode SE, and a drain electrode DE.

A semiconductor layer Act may be disposed on the buffer layer 101. The semiconductor layer Act may include an oxide semiconductor and/or a silicon semiconductor. In the case where the semiconductor layer Act includes an oxide semiconductor, the semiconductor layer Act may include, for example, an oxide of at least one of indium (In), gallium (Ga), stannum (Sn), zirconium (Zr), vanadium (V), hafnium (Hf), cadmium (Cd), germanium (Ge), chromium (Cr), titanium (Ti), or zinc (Zn). As an example, the semiconductor layer Act may be an InSnZnO (“ITZO”) semiconductor layer, an InGaZnO (“IGZO”) semiconductor layer and the like. In the case where the semiconductor layer Act includes a silicon semiconductor, the semiconductor layer Act may include, for example, amorphous silicon or low temperature poly-silicon (“LTPS”).

The gate electrode GE may be disposed on the semiconductor layer Act with the first insulating layer 103 therebetween. The gate electrode GE may overlap a channel region of the semiconductor layer Act. The gate electrode GE may include a low-resistance metal material. As an example, the gate electrode GE may include at least one metal among aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), and copper (Cu) and include a single layer or a multi-layer including the above metals. The gate electrode GE may be connected to a gate line configured to apply electrical signals to the gate electrode GE.

The first insulating layer 103 may be disposed on the buffer layer 101. The first insulating layer 103 may be disposed between the semiconductor layer Act and the gate electrode GE. The first insulating layer 103 may include an inorganic insulating material such as silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), or zinc oxide (ZnO).

The second insulating layer 105 may be disposed on the first insulating layer 103. The second insulating layer 105 may cover the gate electrode GE. Similarly to the first insulating layer 103, the second insulating layer 105 may include an inorganic insulating material including silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), or zinc oxide (ZnO).

An upper electrode CE2 of the storage capacitor Cst may be disposed on the second insulating layer 105. In an embodiment, the upper electrode CE2 may overlap the gate electrode GE. In this case, the gate electrode GE and the upper electrode CE2 overlapping each other with the second insulating layer 105 therebetween may constitute the storage capacitor Cst. That is, the gate electrode GE may serve as a lower electrode CE1 of the storage capacitor Cst. As described above, the storage capacitor Cst and the thin-film transistor TFT may overlap each other. In another embodiment, the storage capacitor Cst and the thin-film transistor TFT may not overlap each other.

The third insulating layer 107 may be disposed on the second insulating layer 105. The third insulating layer 107 may cover the upper electrode CE2. The third insulating layer 107 may include silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), or zinc oxide (ZnO). The third insulating layer 107 may include a single layer or a multi-layer including the inorganic insulating material.

Each of the source electrode SE and the drain electrode DE may be disposed on the third insulating layer 107. The source electrode SE and the drain electrode DE may each be electrically connected to the semiconductor layer Act through a contact hole formed in the first insulating layer 103, the second insulating layer 105, and the third insulating layer 107. The source electrode SE and the drain electrode DE may each include a material having high conductivity. At least one of the source electrode SE or the drain electrode DE may include a conductive material including molybdenum (Mo), aluminum (Al), copper (Cu), and titanium (Ti) and include a single layer or a multi-layer including the above materials. In an embodiment, at least one of the source electrode SE or the drain electrode DE may have a multi-layered structure of Ti/Al/Ti.

The fourth insulating layer 110 may be disposed on the third insulating layer 107. The fourth insulating layer 110 may be disposed on the source electrode SE and the drain electrode DE. Although the fourth insulating layer 110 is shown as a single layer, the embodiment is not limited thereto and the fourth insulating layer 110 may include a multi-layer. The fourth insulating layer 110 may be an organic insulating layer including an organic material. The fourth insulating layer 110 may include an organic insulating material including a general-purpose polymer such as polymethylmethacrylate (“PMMA”) or polystyrene (“PS”), polymer derivatives having a phenol-based group, an acryl-based polymer, an imide-based polymer, an aryl ether-based polymer, an amide-based polymer, a fluorine-based polymer, a p-xylene-based polymer, a vinyl alcohol-based polymer, or a blend thereof. The fourth insulating layer 110 may planarize the upper surface of the pixel circuit PC and planarize a surface on which the light-emitting element LED is disposed.

The light-emitting element LED may be disposed on the fourth insulating layer 110. The light-emitting element LED may be configured to emit, for example, red, green, or blue light, or emit red, green, blue, or white light.

The light-emitting element LED may be an organic light-emitting element including an organic emission layer. Alternatively, the light-emitting element LED may be an inorganic light-emitting element including an inorganic emission layer. The size of the light-emitting element LED may be microscales or nanoscales. As an example, the light-emitting element may be a micro light-emitting element. Alternatively, the light-emitting element LED may be a nanorod light-emitting element. The nanorod light-emitting element may include gallium nitride (GaN). In an embodiment, a color-converting layer may be disposed on the nano-rod light-emitting element. The color-converting layer may include quantum dots. Alternatively, the light-emitting element LED may be a quantum-dot light-emitting diode including a quantum-dot emission layer.

The light-emitting element LED may include a first electrode 210, an intermediate layer 220, and a second electrode 230. Although the first electrode 210 of the light-emitting element LED may be an anode, and the second electrode 230 may be a cathode, the embodiment is not limited thereto. As an example, the light-emitting element LED may be an inverted light-emitting element in which the first electrode 210 is a cathode and the second electrode 230 is an anode. Hereinafter, for convenience of description, description is made based on the light-emitting element LED in which the first electrode 210 is an anode and the second electrode 230 is a cathode.

The first electrode 210 may be disposed on the fourth insulating layer 110. The first electrode 210 may be electrically connected to the thin-film transistor TFT. As an example, the first electrode 210 may be electrically connected to the thin-film transistor TFT through a contact hole of the fourth insulating layer 110.

The first electrode 210 may include a conductive oxide such as indium tin oxide (“ITO”), indium zinc oxide (“IZO”), zinc oxide (ZnO), indium oxide (In₂O₃), indium gallium oxide (“IGO”), or aluminum zinc oxide (“AZO”). In another embodiment, the first electrode 210 may include a reflective layer including silver (Ag), magnesium (Mg), aluminum (Al), platinum (Pt), palladium (Pd), gold (Au), nickel (Ni), neodymium (Nd), iridium (Ir), chrome (Cr), or a compound thereof. In another embodiment, the first electrode 210 may further include a layer on/under the reflective layer, the layer including ITO, IZO, ZnO, or In₂O₃.

A pixel-defining layer 120 may be disposed on the first electrode 210, where the pixel-defining layer 120 includes an opening 1200P exposing the central portion of the first electrode 210. The pixel-defining layer 120 may be disposed on the fourth insulating layer 110.

The intermediate layer 220 may be disposed in the opening 1200P of the pixel-defining layer 120. The intermediate layer 220 may be disposed on the first electrode 210. The intermediate layer 220 may include, for example, an emission layer.

The intermediate layer 220 may include a common layer under and/or on the emission layer. The common layer may include a hole transport layer (“HTL”), a hole injection layer (“HIL”), an electron transport layer (“ETL”), and/or an electron injection layer (“EIL”). Like the second electrode 230, the common layer may cover the plurality of first electrodes 210. In other words, the second electrode 230 and the common layer may share the plurality of light-emitting elements LED.

The second electrode 230 may be disposed on the intermediate layer 220. The second electrode 230 may c cover the substrate 100 in the display area DA entirely. The second electrode 230 may be a light-transmissive electrode or a reflective electrode. The second electrode 230 may include a conductive material having a low work function. As an example, the second electrode 230 may include a (semi) transparent layer including silver (Ag), magnesium (Mg), aluminum (Al), platinum (Pt), palladium (Pd), gold (Au), nickel (Ni), neodymium (Nd), iridium (Ir), chrome (Cr), or an alloy thereof. Alternatively, the second electrode 230 may further include a layer on a (semi) transparent layer, the layer including ITO, IZO, ZnO, or In₂O₃.

The light-emitting element LED may be covered by the encapsulation layer TFE. Although it is shown in FIG. 6 that, like the embodiment described with reference to FIG. 4, the encapsulation layer TFE including the first inorganic thin-film encapsulation layer 310, the second inorganic thin-film encapsulation layer 320, and the hybrid layer 330 covers the light-emitting element LED, this is an example embodiment and the embodiment is not limited thereto. In another embodiment, the encapsulation layer TFE may further include the upper thin-film encapsulation layer UEL as in the embodiment shown in FIG. 5.

As shown in FIG. 6, the first inorganic thin-film encapsulation layer 310 may be a layer most adjacent to the light-emitting element LED among the layers forming the encapsulation layer TFE. The first inorganic thin-film encapsulation layer 310 may be a layer whose distance from the substrate 100 is smallest among the layers forming the encapsulation layer TFE.

A thickness of the first inorganic thin-film encapsulation layer 310 may be less than a thickness of the second inorganic thin-film encapsulation layer 320. Although it is shown that the thickness of the hybrid layer 330 is greater than the thickness of the second inorganic thin-film encapsulation layer 320, the embodiment is not limited thereto and the thickness of the hybrid layer 330 may be variously changed depending on the embodiments. As an example, the thickness of the hybrid layer 330 may be substantially equal to or less than the thickness of the second inorganic thin-film encapsulation layer 320.

Each of the first inorganic thin-film encapsulation layer 310 and the second inorganic thin-film encapsulation layer 320 may be arranged conformal along a layer disposed thereunder.

In an embodiment, the hybrid layer 330 is a layer having a planarization characteristic, and the upper surface of the hybrid layer 330 may be substantially flat.

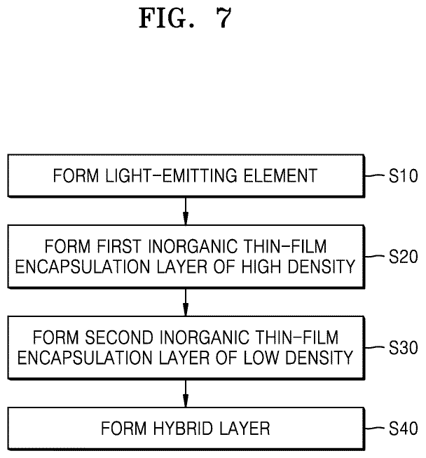

FIG. 7 is a flowchart showing a method of manufacturing the display apparatus 1 according to an embodiment. FIG. 7 shows a method of forming the display apparatus 1 including the encapsulation layer TFE according to an embodiment described with reference to FIG. 4.

Referring to FIGS. 4, 6, and 7, the light-emitting element LED may be formed over the substrate 100 (S10). In an embodiment, the pixel circuit layer PCL including the pixel circuit PC may be formed on the substrate 100, and the light-emitting element LED may be formed on the pixel circuit layer PCL.

Next, the first inorganic thin-film encapsulation layer 310 of a high density may be formed on the light-emitting element LED (S20). A film density of the first inorganic thin-film encapsulation layer 310 may be formed, for example, in a range of about 2.70 g/cm³ to about 4.00 g/cm³.

The first inorganic thin-film encapsulation layer 310 may be formed by a deposition process. The first inorganic thin-film encapsulation layer 310 may be deposited at a deposition rate of less than 300 Å/min. As an example, the first inorganic thin-film encapsulation layer 310 may be formed by an atomic layer deposition (ALD). As an example, the first inorganic thin-film encapsulation layer 310 may be formed by a plasma enhanced atomic layer deposition (PEALD). Accordingly, the first inorganic thin-film encapsulation layer 310 may have a single atomic layer, and the thickness TH1 of the first inorganic thin-film encapsulation layer 310 may be formed to be 50 angstroms (Å) or less.

The first inorganic thin-film encapsulation layer 310 may be formed by using a compound containing a silicon element and a nitrogen element as a precursor. As an example, the first inorganic thin-film encapsulation layer 310 may be formed by using a silicone amine-based compound as a precursor.

The first inorganic thin-film encapsulation layer 310 may include an inorganic material. As an example, the first inorganic thin-film encapsulation layer 310 may include at least a silicon (Si) element and a nitrogen (N) element. As an example, the first inorganic thin-film encapsulation layer 310 may include silicon nitride (SiNₓ) or silicon oxynitride (SiOₓN_{y}). As an example, the ratio of nitrogen elements to silicon elements in the first inorganic thin-film encapsulation layer 310 may be less than 0.75. As an example, the refractive index of the first inorganic thin-film encapsulation layer 310 may be 1.85 or more.

Next, the second inorganic thin-film encapsulation layer 320 of a high density may be formed on the first inorganic thin-film encapsulation layer 310. A film density of the second inorganic thin-film encapsulation layer 320 may be formed less than a film density of the first inorganic thin-film encapsulation layer 310. A film density of the second inorganic thin-film encapsulation layer 320 may be formed, for example, in a range of about 1.7 g/cm³ to about 2.10 g/cm³.

The second inorganic thin-film encapsulation layer 320 may be formed by a deposition process. The second inorganic thin-film encapsulation layer 320 may be deposited at a deposition rate of 300 Å/min or more. In an embodiment, the second inorganic thin-film encapsulation layer 320 may be formed by a different deposition process from a deposition process of the first inorganic thin-film encapsulation layer 310. In another embodiment, the second inorganic thin-film encapsulation layer 320 may be formed by the same deposition process as the first inorganic thin-film encapsulation layer 310 but formed at a different deposition rate. As an example, the second inorganic thin-film encapsulation layer 320 may be formed by chemical vapor deposition (CVD) or ALD As an example, the second inorganic thin-film encapsulation layer 320 may be formed by a PECVD or a PEALD.

The thickness TH2 of the second inorganic thin-film encapsulation layer 320 may be greater than the thickness TH1 of the first inorganic thin-film encapsulation layer 310.

The second inorganic thin-film encapsulation layer 320 may be formed by using a compound containing a silicon element and a nitrogen element as a precursor. As an example, the second inorganic thin-film encapsulation layer 320 may be formed by using a silicone amine-based compound as a precursor.

The second inorganic thin-film encapsulation layer 320 may include an inorganic material. As an example, the second inorganic thin-film encapsulation layer 320 may include at least a silicon (Si) element and a nitrogen (N) element. As an example, the second inorganic thin-film encapsulation layer 320 may include silicon nitride (SiNₓ) or silicon oxynitride (SiOₓN_{y}). In an embodiment, the ratio of nitrogen elements to silicon elements in the second inorganic thin-film encapsulation layer 320 may be greater than the ratio of nitrogen elements to silicon elements in the first inorganic thin-film encapsulation layer 310. As an example, the ratio of nitrogen elements to silicon elements in the second inorganic thin-film encapsulation layer 320 may exceed 0.77. In an embodiment, a refractive index of the second inorganic thin-film encapsulation layer 320 may be less than a refractive index of the first inorganic thin-film encapsulation layer 310. As an example, the refractive index of the second inorganic thin-film encapsulation layer 320 may be about 1.75 to about 1.90.

Next, the hybrid layer 330 may be formed on the second inorganic thin-film encapsulation layer 320 (S40).

The hybrid layer 330 may be formed using a precursor containing at least one of a compound having an N—Si bond or a compound having an O—Si-based bond. As an example, the hybrid layer 330 may include, as a precursor, at least one of cyclosilazane, trisilyamine, bis(diethylamino)silane, bis(t-butylamino)silane, tris(dimethylamino)silane, tris(isopropylamino)silane, tetrakis(dimethylamino)silane, tri(isopropyl)cyclotrisilazane, and tetramethyldisilazane.

The hybrid layer 330 is an organic-inorganic hybrid layer including organic moiety and, as shown in FIG. 6, may be formed to have a substantially flat upper surface. As an example, the hybrid layer 330 may include at least a silicon element and a carbon element and may further include a nitrogen element or an oxygen element. As an example, the hybrid layer 330 may include at least one of silicon carbonitride (SiCₓN_{y}), silicon oxycarbide (SiOₓC_{y}), or silicon oxycarbonitride (SiOₓC_{y}N_{z}).

A film density of the hybrid layer 330 may be less than a film density of the first inorganic thin-film encapsulation layer 310. A film density of the hybrid layer 330 may be formed, for example, in a range of about 1.7 g/cm³ to about 2.10 g/cm³.

The hybrid layer 330 may be formed by a deposition process. The hybrid layer 330 may be deposited at a deposition rate of 300 Å/min or more. As an example, the hybrid layer 330 may be formed by CVD or ALD.

In an embodiment, a refractive index of the hybrid layer 330 may be less than a refractive index of the first inorganic thin-film encapsulation layer 310. As an example, the refractive index of the hybrid layer 330 may be about 1.75 to about 1.90.

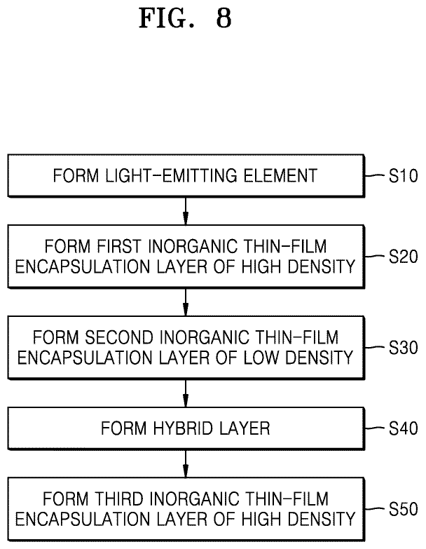

FIG. 8 is a schematic flowchart showing a method of manufacturing the display apparatus 1 according to an embodiment. FIG. 8 shows a method of forming the display apparatus 1 including the encapsulation layer TFE according to another embodiment described with reference to FIG. 5. FIG. 8 is a modified embodiment of FIG. 7, and descriptions repeated in FIG. 7 are omitted.

Referring to FIGS. 5, 6, and 7, the hybrid layer 330 is formed, then the third inorganic thin-film encapsulation layer of a high density may be further formed on the hybrid layer 330 (S50). The third inorganic thin-film encapsulation layer may correspond to the upper thin-film encapsulation layer UEL described with reference to FIG. 5.

A film density of the third inorganic thin-film encapsulation layer may be formed greater than a film density of the second inorganic thin-film encapsulation layer 320. A film density of the third inorganic thin-film encapsulation layer may be formed, for example, in a range of about 2.70 g/cm³ to about 4.00 g/cm³.

The third inorganic thin-film encapsulation layer may be formed by a deposition process. The third inorganic thin-film encapsulation layer may be deposited at a deposition rate of less than 300 Å/min. In an embodiment, although the third inorganic thin-film encapsulation layer may be formed by the same process as the first inorganic thin-film encapsulation layer 310, the embodiment is not limited thereto. As an example, the third inorganic thin-film encapsulation layer may be formed by chemical vapor deposition (CVD) or ALD.

In an embodiment, although the thickness of the third inorganic thin-film encapsulation layer may be formed less than the thickness of the second inorganic thin-film encapsulation layer 320, the embodiment is not limited thereto.

The third inorganic thin-film encapsulation layer may be formed by using a compound containing a silicon element and a nitrogen element as a precursor. As an example, the third inorganic thin-film encapsulation layer may be formed by using a silicone amine-based compound as a precursor.

The third inorganic thin-film encapsulation layer may include an inorganic material. As an example, the third inorganic thin-film encapsulation layer may include at least a silicon (Si) element and a nitrogen (N) element. As an example, the third inorganic thin-film encapsulation layer may include silicon nitride (SiNₓ) or silicon oxynitride (SiOₓN_{y}). As an example, the ratio of nitrogen elements to silicon elements in the third inorganic thin-film encapsulation layer may be less than 0.75. As an example, the refractive index of the third inorganic thin-film encapsulation layer may be 1.85 or more.

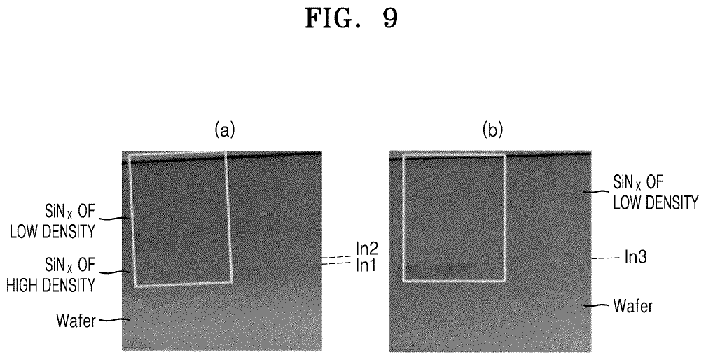

FIG. 9 is a view showing analysis results of TEM according to an embodiment and a comparative example. FIG. 9 shows depositing a silicon nitride layer of a low density using the same deposition process and the same precursor, and shows an embodiment of forming a silicon nitride layer of a high density under the silicon nitride layer of a low density, and a comparative example of not forming the silicon nitride layer of a high density. (a) of FIG. 9 shows an embodiment of depositing a silicon nitride layer of a relatively high density on a wafer, then depositing a silicon nitride layer of a relatively low density, and (b) FIG. 9 shows a comparative example of depositing a silicon nitride layer of a low density directly on a wafer without depositing a silicon nitride layer of a high density.

The embodiment in (a) of FIG. 9 shows an interface In1 between a wafer and a silicon nitride layer of a high density, and an interface In2 between a silicon nitride layer of a high density and a silicon nitride layer of a low density. The comparative example in (b) of FIG. 9 shows an interface In3 between a wafer and a silicon nitride layer of a low density.

Referring to (a) of FIG. 9, in the case where a silicon nitride layer of a low density is deposited on a silicon nitride layer of a high density as in the embodiment, it is shown that the interface In2 between the silicon nitride layer of a high density and the silicon nitride layer of a low density is not clear.

In contrast, in the case where a silicon nitride layer of a low density is deposited directly on a wafer without depositing a silicon nitride layer of a high density as in the comparative example, it is shown that the interface In3 between the wafer and the silicon nitride layer of a low density clearly appears.

This is because interatomic bonds are formed at the interface In2 where the silicon nitride layer of a high density meets the silicon nitride layer of a low density in the embodiment, unlike the comparative example in which the silicon nitride layer of a high density is not disposed in the lower portion, a film density of the silicon nitride layer of a low density is formed relatively great at an initial stage when the silicon nitride layer of a low density is formed. That is, in the case where the silicon nitride layer of a high density is formed in the lower portion first, and the silicon nitride layer of a low density is formed thereon, it is determined that a film density of the silicon nitride layer of a low density in a region adjacent to the interface formed in the initial stage is formed relatively great, and thus, a barrier characteristic is effectively improved.

As described above, because the encapsulation layer TFE according to the embodiments commonly includes the first inorganic thin-film encapsulation layer 310 of a high density and the second inorganic thin-film encapsulation layer 320 of a low density thereon, a barrier characteristic of the encapsulation layer TFE may be effectively improved. In addition, because the embodiment includes the first inorganic thin-film encapsulation layer 310 of a high density, the barrier characteristic of the encapsulation layer TFE is effectively improved, and the thickness of the lower thin-film encapsulation layer LEL disposed under the hybrid layer 330 may be formed thinner than the case where the first inorganic thin-film encapsulation layer 310 is not included, and thus, the entire thickness of the encapsulation layer TFE in an embodiment may be effectively reduced.

Because the display apparatus according to an embodiment includes the encapsulation layer including the first inorganic thin-film encapsulation layer of a high density, the second inorganic thin-film encapsulation layer of a low density disposed on the first inorganic thin-film encapsulation layer, and the hybrid layer on the second inorganic thin-film encapsulation layer, the thin and lightweight display apparatus may be provided. However, this effect is an example, and the scope of the disclosure is not limited by this effect.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A display apparatus comprising:
a substrate;
a light-emitting element disposed on the substrate; and
an encapsulation layer covering the light-emitting element and including a first inorganic thin-film encapsulation layer, a second inorganic thin-film encapsulation layer, and a hybrid layer,
wherein the second inorganic thin-film encapsulation layer is disposed on the first inorganic thin-film encapsulation layer and has a film density less than a film density of the first inorganic thin-film encapsulation layer, and
the hybrid layer is disposed on the second inorganic thin-film encapsulation layer and includes a silicon element and a carbon element and further includes a nitrogen element or an oxygen element.

2. The display apparatus of claim 1, wherein a thickness of the first inorganic thin-film encapsulation layer is less than a thickness of the second inorganic thin-film encapsulation layer.

3. The display apparatus of claim 1, wherein the hybrid layer has a film density less than the film density of the first inorganic thin-film encapsulation layer.

4. The display apparatus of claim 1, wherein each of the first inorganic thin-film encapsulation layer and the second inorganic thin-film encapsulation layer includes a silicon element and a nitrogen element.

5. The display apparatus of claim 4, wherein a ratio of the nitrogen element to the silicon element in the first inorganic thin-film encapsulation layer is less than a ratio of the nitrogen element to the silicon element in the second inorganic thin-film encapsulation layer.

6. The display apparatus of claim 1, wherein the film density of the first inorganic thin-film encapsulation layer is in a range of about 2.70 grams per cubic centimeter (g/cm³) to about 4.00 g/cm³.

7. The display apparatus of claim 1, wherein the film density of the second inorganic thin-film encapsulation layer is in a range of about 1.70 g/cm³ to about 2.10 g/cm³.

8. The display apparatus of claim 1, wherein a refractive index of the first inorganic thin-film encapsulation layer is greater than a refractive index of the second inorganic thin-film encapsulation layer.

9. The display apparatus of claim 1, wherein the encapsulation layer further includes a third inorganic thin-film encapsulation layer disposed on the hybrid layer.

10. The display apparatus of claim 9, wherein a film density of the third inorganic thin-film encapsulation layer is greater than the film density of the second inorganic thin-film encapsulation layer.

11. The display apparatus of claim 1, wherein the hybrid layer includes at least one of silicon carbonitride (SiCₓN_{y}), silicon oxycarbide (SiOₓC_{y}), or silicon oxycarbonitride (SiOₓC_{y}N_{z}).

12. A display apparatus comprising:
a substrate;
a light-emitting element disposed on the substrate; and
an encapsulation layer covering the light-emitting element,
wherein the encapsulation layer includes a first inorganic thin-film encapsulation layer disposed in a lowermost portion of the encapsulation layer, a second inorganic thin-film encapsulation layer disposed directly on the first inorganic thin-film encapsulation layer and having a film density less than a film density of the first inorganic thin-film encapsulation layer, and a hybrid layer disposed on the second inorganic thin-film encapsulation layer and having a film density less than the film density of the first inorganic thin-film encapsulation layer.

13. The display apparatus of claim 12, wherein the hybrid layer includes a silicon element and a carbon element and further includes a nitrogen element or an oxygen element.

14. The display apparatus of claim 12, wherein a thickness of the first inorganic thin-film encapsulation layer is less than a thickness of the second inorganic thin-film encapsulation layer.

15. A method of manufacturing a display apparatus, the method comprising:
forming a light-emitting element on a substrate;
forming a first inorganic thin-film encapsulation layer on the light-emitting element;
forming, on the first inorganic thin-film encapsulation layer, a second inorganic thin-film encapsulation layer having a film density less than a film density of the first inorganic thin-film encapsulation layer; and
forming, on the second inorganic thin-film encapsulation layer, a hybrid layer including a silicon element and a carbon element and further including a nitrogen element or an oxygen element.

16. The method of claim 15, wherein a deposition rate of the first inorganic thin-film encapsulation layer is less than a deposition rate of the second inorganic thin-film encapsulation layer.

17. The method of claim 15, wherein a thickness of the first inorganic thin-film encapsulation layer is less than a thickness of the second inorganic thin-film encapsulation layer.

18. The method of claim 15, wherein the hybrid layer has a film density less than the film density of the first inorganic thin-film encapsulation layer.

19. The method of claim 15, wherein the forming of the first inorganic thin-film encapsulation layer comprises using an atomic layer deposition method.

20. The method of claim 15, wherein the forming of the hybrid layer comprises using a precursor containing at least one of a compound having an N—Si bond or a compound having an O—Si-based bond.
